(19) United States
(12) Patent Application Publication
(10) Pub. No.: US 2006/0267147 A1
(43) Pub. Date: Nov. 30, 2006

(54) Semiconductor device having current mirror circuit

(75) Inventors: Kingo Ota, Nukata-gun (JP); Shoichi Okuda, Nukata-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/442,399

(22) Filed: May 30, 2006

(30) Foreign Application Priority Data
May 30, 2005 (JP) 2005-157507

(51) Int. Cl. H01L 27/082

(52) U.S. Cl. 257/566

(57) ABSTRACT

A semiconductor device includes a semiconductor substrate and a current mirror circuit that has an input transistor group of input transistors and an output transistor group of output transistors. The input transistor group and the output transistor group are arranged on the semiconductor substrate in such a manner that at least one of the input transistors and at least one of the output transistors are grouped together to form a transistor set. Each transistor set is arranged in a repeating pattern. In each transistor set, the transistors have the same temperature and show the same temperature dependence, even when a temperature gradient occurs inside the semiconductor device. Thus, a mirror ratio of the current mirror circuit can be accurately obtained.

### CROSS REFERENCE TO RELATED APPLICATION

This application is based on and incorporates herein by reference Japanese Patent Application No. 2005-157507 filed on May 30, 2005.

### FIELD OF THE INVENTION

The present invention relates to a semiconductor device having a current mirror circuit.

### BACKGROUND OF THE INVENTION

A semiconductor device disclosed in JP-A-6-138967 has a current mirror circuit in which an output current mirrors an input current by a predetermined ratio.

FIG. 4A is a schematic circuit diagram of a current mirror circuit 200 according to a related art. As shown in FIG. 4A, the current mirror circuit includes a transistor group JA of transistors JA1-JAk, a transistor group JB of transistors JB1-JBm, and a transistor group JC of transistors JC1-JCn, where k, m, and n are positive integers. All bases of the transistors JA1-JAk, JB1-JBm, and JC1-JCn are electrically connected together.

When a constant current source J1 provides a base current ib, a current i1 flows through the transistor group JA. Then, currents i2, i3 flow through the transistor groups JB, JC, respectively. In this case, the currents i2, i3 mirror the current i1 by respective ratios.

FIG. 4B is a schematic top view of a layout in which the current mirror circuit 200 is disposed on a semiconductor substrate of the semiconductor device. As shown in FIG. 4B, each of the transistors JA1-JAk, JB1-JBm, and JC1-JCn has a base J2, an emitter J3, and a collector J4. The semiconductor substrate has a base electrode J5, an emitter electrode J6, collector electrodes J7, and collector wirings J9a-J9c that are electrically separated from each other. The base electrode J5 has a straight-line shape and is arranged to overlap each base J2. Likewise, the emitter electrode J6 has a straight-line shape and is arranged to overlap each emitter J3. Each of the collector electrodes J7 is arranged on each of the transistors JA1-JAk, JB1-JBm, and JC1-JCn. Wiring members J8 extend to an upper layer of the collector electrodes J7. In the transistor group JA, each of the collector electrodes 7 is electrically connected to the collector wiring J9a. In the transistor group JB, each of the collector electrodes 7 is electrically connected to the collector wiring J9b. In the transistor group JC, each of the collector electrodes 7 is electrically connected to the collector wiring J9c. Thus, the transistors JA1-JAk, JB1-JBm, and JC1-JCn are arranged together as the transistor groups JA, JB and JC in respective areas.

When a semiconductor device having the current mirror circuit 200 includes a heat-generating element such as a field-effect transistor (FET), heat generated by the heat-generating element affects the current mirror circuit 200. Because the heat is not equally transferred inside the semiconductor device, a temperature gradient (temperature deference) occurs inside the semiconductor device. As a result of the occurrence of the temperature gradient, one of the transistors JA1-JAk, one of the transistors JB1-JBm, and one of the transistors JC1-JCn have different current value. Therefore, a mirror ratio of the current mirror circuit 200 cannot be accurately obtained.

If the semiconductor device is based on a silicon-on-insulator (SOI) substrate, each of the transistors JA1-JAk, JB1-JBm, and JC1-JCn is separated from each other by an insulation layer. Therefore, heat conductivity inside the semiconductor device may be decreased and the temperature gradient may be increased accordingly.

### SUMMARY OF THE INVENTION

In view of the above-described problem, it is an object of the present invention to provide a semiconductor device having a current mirror circuit, a mirror ratio of which can be accurately obtained even when a temperature gradient occurs inside the semiconductor device.

A semiconductor device includes a semiconductor substrate and a current mirror circuit that has an input transistor group of input transistors and an output transistor group of output transistors. The input transistor group and the output transistor group are arranged on the semiconductor substrate in such a manner that at least one of the input transistors and at least one of the output transistors are grouped together to form a transistor set. The transistor set is arranged in a repeating pattern.

When a temperature gradient occurs inside the semiconductor device, each transistor set may has a different temperature. In other words, there may appear a temperature difference between one transistor set and another transistor set. In each transistor set, however, the transistors have the same temperature and show the same temperature dependence. Consequently, the input transistor group and the output transistor group show the same temperature dependence. Thus, even when the temperature gradient occurs inside the semiconductor device, a mirror ratio of the current mirror circuit can be accurately obtained.

### BRIEF DESCRIPTION OF THE DRAWINGS

The above and other objectives, features and advantages of the present invention will become more apparent from the following detailed description made with reference to the accompanying drawings. In the drawings:

FIG. 1A is a schematic circuit diagram of a current mirror circuit included in a semiconductor device according to an embodiment of the present invention, FIG. 1B is a view showing a layout in which the current mirror circuit of FIG. 1A are disposed on a semiconductor substrate of the semiconductor device, and FIG. 1C is a view showing another layout in which the current mirror circuit of FIG. 1A are disposed on the semiconductor substrate of the semiconductor device;

FIG. 2 is a circuit diagram of a squib driver circuit as an application of the current mirror circuit of FIGS. 1A-1C;

FIG. 3A is a graph illustrating a change in a firing current in the squib driver circuit of FIG. 2 including the current mirror circuit of FIGS. 1A-1C, FIG. 3B is a graph illustrating a change in a firing current in the squib driver circuit of FIG. 2 including a current mirror circuit of FIGS. 4A and 4B; and

FIG. 4A is a circuit diagram of the current mirror circuit included in a semiconductor device according to a related art, and FIG. 4B is a view showing a layout in which the current mirror circuit of FIG. 4A is disposed on a semiconductor substrate of the semiconductor device.

### DETAILED DESCRIPTION OF THE PREFERRED EMBODIMENT

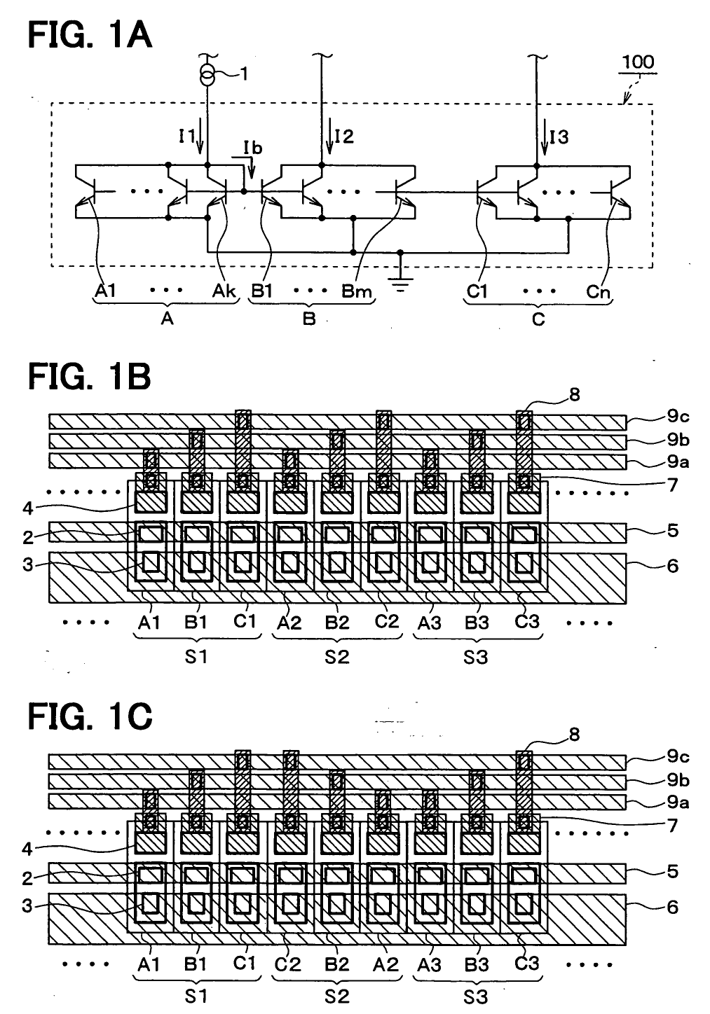

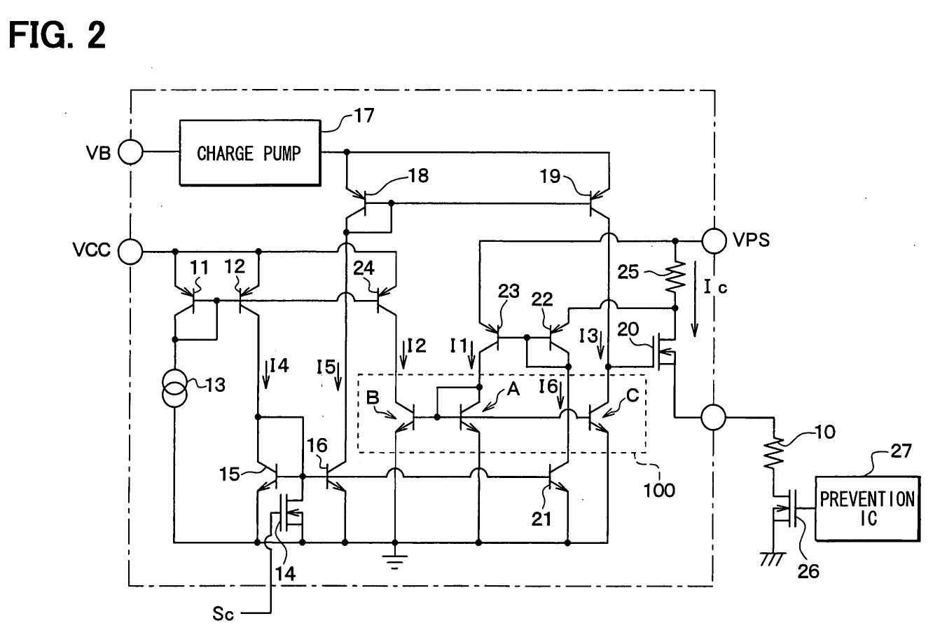

A semiconductor device having a current mirror circuit 100 according to an embodiment of the present invention will now be described with reference to FIGS. 1A-1C and 2.

As shown in FIG. 1A, the current mirror circuit 100 includes an input transistor group A of input transistors A1-Ak, a first output transistor group B of output transistors B1-Bm, and a second output transistor group C of output transistors C1-Cn, where k, m, and n are positive integers. All bases of the transistors A1-Ak, B1-Bm, and C1-Cn are electrically connected together.

In the current mirror circuit 100, when a constant current source 1 provides a constant base current Ib, a current I1 flows through the transistor group A. Then, currents I2, I3 flow through the transistor groups B, C, respectively. The current I2, I3 mirror the current I1 by respective mirror ratios.

As shown in FIG. 1B, each of the transistors A1-Ak, B1-Bm, and C1-Cn has a base 2, an emitter 3, and a collector 4. A semiconductor substrate on which the current mirror circuit 100 is disposed has a base electrode 5, an emitter electrode 6, collector electrodes 7, and collector wirings 9a-9c that are electrically separated from each other. The base electrode 5 has a straight-line shape and is arranged to overlap each base 2. Likewise, the emitter electrode 6 has a straight-line shape and is arranged to overlap each emitter 3. Each of the collector electrodes 7 is arranged on each of the transistors A1-Ak, B1-Bm, and C1-Cn. Wiring members 8 extend to an upper layer of the collector electrodes 7. In the transistor group A, each of the collector electrodes 7 is electrically connected to the collector wiring 9a. In the transistor group B, each of the collector electrodes 7 is electrically connected to the collector wiring 9b. In the transistor group C, each of the collector electrodes 7 is electrically connected to the collector wiring 9c.

In the semiconductor device, the current mirror circuit 100 is disposed on the semiconductor substrate in such a manner that one of the transistors A1-Ak, one of the transistors B1-Bm, and one of the transistors C1-Cn are grouped together to form a transistor set. As shown in FIG. 1B, for example, a first transistor set S1 includes the transistors A1, B1, and C1 that are arranged in that order, a second transistor set S2 includes the transistors A2, B2, and C2 that are arranged in that order, and a third transistor set S3 includes the transistors A3, B3, and C3 that are arranged in that order. Alternatively, in the second transistor set S2, the transistors C2, B2, and A2 may be arranged in that order as shown in FIG. 1C. Each transistor set is arranged in a repeating pattern.

When the semiconductor device has a heat-generating element such as a FET, heat generated by the heat-generating element is transferred inside the semiconductor device and a temperature gradient occurs inside the semiconductor device. As a result of the occurrence of the temperature gradient, each transistor set has a different temperature. In each transistor set, however, the transistors have the same temperature.

For example, when the temperature gradient occurs inside the semiconductor device, there may appear a temperature difference between the first transistor set S1 and the third transistor set S3 due to distance between the first transistor set S1 and the third transistor set S3. In the first transistor set S1, however, the transistors A1, B1, and C1 have the same temperature and show the same temperature dependence. Likewise, in the third transistor set S3, the transistors A3, B3, and C3 have the same temperature and show the same temperature dependence. Therefore, the transistor groups A, B, and C shows the same temperature dependence.

Thus, even when the temperature gradient occurs inside the semiconductor device, temperature gradients between the transistor groups A, B, and C can be reduced so that a mirror ratio of the current mirror circuit 100 can be accurately obtained.

The current mirror circuit 100 may be, for example, used for a squib driver circuit as shown in FIG. 2. In FIG. 2, a portion of the squib driver circuit enclosed by a long and short dash line is integrated into the semiconductor device.

The squib driver circuit controls gas charge into an airbag mounted on a vehicle. Specifically, the squib driver circuit controls a firing current Ic provided to a squib load 10, which may be, for example, a resistor. When a need to inflate the airbag arises, the squib driver circuit provides the firing current Ic to the squib load 10 in order to heat the squib load 10 to high heat. The heated squib load 10 causes a gas explosion. Thus, the airbag is filled with gas and inflated.

The squib driver circuit includes PNP transistors 11, 12, bases of which are connected to each other, a constant current source 13, and a charge pump circuit 17. The squib driver circuit generates a constant current based on a first predetermined voltage VCC and controls the firing current Ic based on the constant current. The charge pump circuit 17 increases a second predetermined voltage VB to, for example, 32 volts and provides an electric current to PNP transistors 18, 19, bases of which are connected to each other.

In normal times when no collision is detected, a metal oxide semiconductor (MOS) transistor 14 is kept in an ON state by an airbag control signal Sc that is input to the base of the MOS transistor 14. Accordingly, NPN transistors 15, 16, bases of which are connected to each other, are kept in an OFF state and the PNP transistors 18, 19 are kept in the OFF state. Thus, a MOS transistor 20 is kept in the OFF state and no firing current Ic flows through the squib load 10.

In contrast, when the collision is detected, the MOS transistor 14 is turned off by the airbag control signal Sc. Then, a current I4 flows through the transistor 15 and a current I5 that mirrors the current I4 flows through the transistor 16. Thus, the transistors 18, 19 are turned on and the current I3 flows through the transistor group C. Therefore, the MOS transistor 20 is turned on.

Further, a current I6 that mirrors the current I4 flows through a NPN transistor 21 connected to the transistor 15 in a current-mirror configuration. Thus, PNP transistors 22, 23, bases of which are connected to each other, are turned on and the current I1 flows through the transistor group A. Further, a PNP transistor 24 connected to the transistor 11 in a current mirror configuration is supplied with an electric current based on the voltage VCC and the current I2 flows through the transistor group B.

Thus, when the collision is detected, the currents I1-I3 flow through the transistor groups A-C of the current mirror circuit 100, respectively.

As shown in FIG. 2, a power supply voltage VPS is applied to the squib driver circuit through a terminal. The voltage VPS allows the firing current Ic to flow through the squib load 10 via a shunt resistor 25. When the firing current Ic flows through the shunt resistor 25, a voltage drop occurs across the shunt resistor 25. As a result of the occurrence of the voltage drop, there appears a difference between a voltage between the terminal to which the voltage VPS is applied and the base of the transistor 22 and a voltage between the terminal to which the voltage VPS is applied and the base of the transistor 23. Therefore, the current I1 changes in accordance with the difference.

The current I6 flowing through the transistor 22 is constant and the current I3 flowing through the transistor group C depends on the current I1. Therefore, the gate voltage of the MOS transistor 20 depends on the current I1 and the firing current Ic also depends on the current I1.

When the firing current Ic changes, the voltage drop across the shunt resistor 25 changes accordingly. As a result of the change in the voltage drop, the current I1 changes and the current I3 changes accordingly. Thus, the gate voltage of the MOS transistor 20 is feedback-controlled so that the firing current Ic can be kept constant at a desired value.

In the squib driver circuit, a MOS transistor 26 is connected to the squib load 10 in a low side configuration and controlled by a prevention integrated circuit (IC) 27. When the collision is not detected, the prevention circuit 27 keeps the MOS transistor 26 in the OFF state to prevent the firing current Ic from accidentally flowing through the squib load 10.

If the mirror ratio of the current mirror circuit 100 changes, for example, due to heat generated by the MOS transistor 20, the firing current Ic changes accordingly. Therefore, the firing current Ic cannot be kept constant at the desired value.

In the embodiment, the current mirror circuit 100 is disposed on the semiconductor substrate in such a manner that one of the transistors A1-Ak, one of the transistors B1-Bm, and one of the transistors C1-Cn are grouped together to form the transistor set. Thus, even when the temperature gradient occurs inside the semiconductor device, the temperature gradient between the transistor groups A, B, and C can be reduced so that the mirror ratio of the current mirror circuit 100 can be accurately obtained.

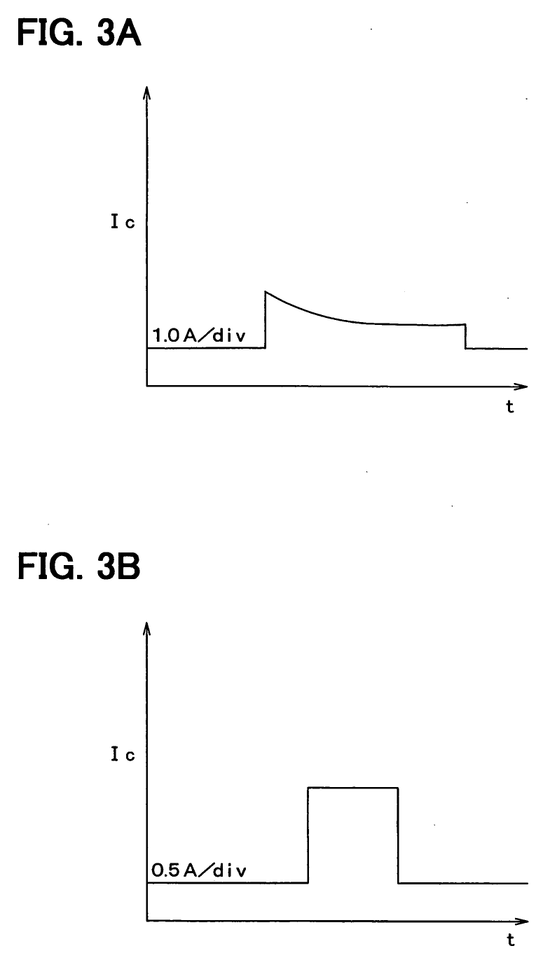

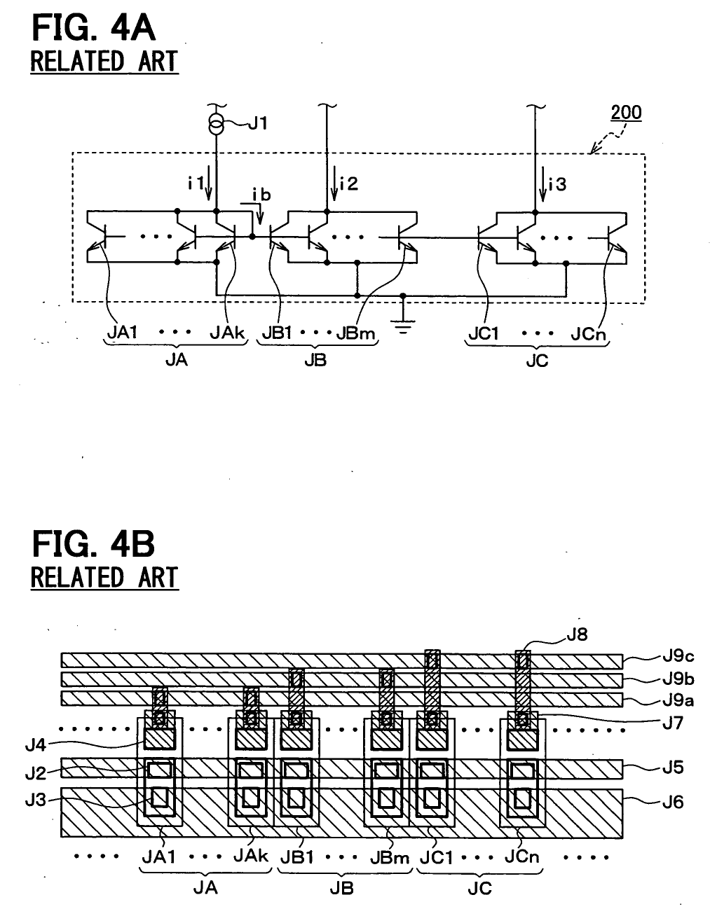

FIG. 3A is a graph illustrating a change in the firing current Ic in the squib driver circuit including the current mirror circuit 200 arranged as shown in FIG. 4B. As can be seen from the graph, the firing current Ic gradually changes, because the mirror ratio of the current mirror circuit 200 changes due to the temperature gradient that occurs inside the semiconductor device.

FIG. 3B is a graph illustrating a change in the firing current Ic in the squib driver circuit including the current mirror circuit 100 arranged as shown in FIG. 1B. As can be seen from the graph, the firing current Ic is kept constant, because the mirror ratio of the current mirror circuit 100 is accurately obtained despite the temperature gradient that occurs inside the semiconductor device.

The embodiment described above may be modified in various ways. For example, transistors A1-Ak, B1-Bm, and C1-Cn may be different in number (i.e., k≠m≠n). In this case, for example, one of the transistors A1-Ak, two of the transistors B1-Bk, and one of the transistors C1-Ck may be grouped together to form the transistor set. If some of the transistors B1-Bk and some of the transistors C1-Ck are left when one of the transistors A1-Ak, one of the transistors B1-Bk, and one of the transistors C1-Ck are grouped together to form the transistor set, one of the left transistors B1-Bk and one of the left transistors C1-Ck may be grouped together to form the transistor set.

The current mirror circuit 100 may include two transistor groups or four or more transistor groups.

The semiconductor device may be based on various types of semiconductor substrate such as a single silicon substrate or a SOI substrate.

Such changes and modifications are to be understood as being within the scope of the present invention as defined by the appended claims.

What is claimed is:

1. A semiconductor device, comprising:
a semiconductor substrate; and
a current mirror circuit including an input transistor group of a plurality of input transistors and an output transistor group of a plurality of output transistors, wherein
the input transistor group and the output transistor group are arranged on the semiconductor substrate in such a manner that at least one of the input transistors and at least one of the output transistors are grouped together to form a transistor set, and
each transistor set is arranged in a repeating pattern.

2. The semiconductor device according to claim 1, wherein
the transistor set has a first transistor set and a second transistor set,
the first transistor set includes at least one of the input transistors and at least one of the output transistors, the input and output transistors being arranged in a first order,
the second transistor set includes at least one of the input transistors and at least one of the output transistors, the input and output transistors being arranged in a second order different from the first order, and
the first transistor set and the second transistor set are alternately arranged in the repeating pattern.

3. The semiconductor device according to claim 1, wherein
the output transistor group has a first output transistor group of a first portion of the output transistors and a second output transistor group of a second portion of the output transistors, and
each transistor set includes at least one of the input transistors of the input transistor group, at least one of the output transistors of the first output transistor group, and at least one of the output transistors of the second output transistor group.

4. The semiconductor device according to claim 3, wherein
the transistor set has a first transistor set and a second transistor set,
the first transistor set includes at least one of the input transistors of the input transistor group, at least one of the output transistors of the first output transistor group, and at least one of the output transistors of the second output transistor group, the input and output transistors being arranged in a first order,
the second transistor set includes at least one of the input transistors of the input transistor group, at least one of the output transistors of the first output transistor group, and at least one of the output transistors of the second output transistor group, the input and output transistors being arranged in a second order different from the first order, and
the first transistor set and the second transistor set are alternately arranged in the repeating pattern.

5. The semiconductor device according to claim 1, wherein
the semiconductor substrate is a silicon-on-insulator substrate having an insulation layer, and
each of the input and output transistors is separated from each other by the insulation layer.

6. The semiconductor device according to claim 1, further comprising:
a heat generating element electrically connected to the current mirror circuit.

7. The semiconductor device according to claim 1, wherein
the current mirror circuit is a portion of a squib driver circuit for activating a squib.
